(19) United States
(12) Patent Application Publication
(10) Pub. No.: US 2016/0081207 A1
(43) Pub. Date: Mar. 17, 2016

(54) MOUNT FOR PORTABLE ELECTRONIC DEVICES

(71) Applicants: TomTom International B.V., Amsterdam (NL); TomTom Software Ltd., London (GB)

(72) Inventors: Samuel Mark Broadbent, Amsterdam (NL); Mark Lee Dempsey, Beckenham (GB); Andrew John Roy Tattersfield, Amsterdam (NL); Daniel Browning, Amsterdam (NL)

(21) Appl. No.: 14/785,360

(22) PCT Filed: Apr. 17, 2014
(86) PCT No.: PCT/EP2014/057979

§ 371 Date: Oct. 19, 2015

(30) Foreign Application Priority Data
Apr. 17, 2013 (GB) 1306995.0

(51) Int. Cl. H05K 5/02; H05K 5/00; F16C 11/06

(52) U.S. Cl. CPC H05K 5/0204; F16C 11/06; H05K 5/0086; H05K 5/0221

(57) ABSTRACT

A mount 290 for a portable electronic device 201 comprises a support cradle 202 arranged to engage against a surface of a device 201 mounted thereto. The support cradle 202 comprises a power connector having one or more electrical contacts to deliver electrical power to the device 201. A bearing arrangement connects the support cradle 202 to the mount 290 such that the support cradle 202 is rotatable about at least two orthogonal axes passing through a fixed point defined by the mount 290.

### FIELD OF INVENTION

The present invention relates to mounts for portable electronic devices, such as mobile phones, smart phones, PDAs, tablet computers, other handheld personal computers, portable audio systems (e.g. radio players, MP3 players, etc), multimedia players, games consoles, and portable navigation devices (so-called PNDs).

### BACKGROUND OF THE INVENTION

Various measures have been taken to mount portable electronic devices, such as portable navigation devices for use in vehicles. For example, it is known to mount such electronic equipment in cradles or holders located on the vehicle dashboard or attached to the windscreen. These mounting solutions can be permanent, e.g. where the cradle is screwed or glued to the dashboard, or temporary, e.g. where the cradle is held in place using a suction cup. Some mounting solutions provide a gooseneck so as to allow the cradle to extend away from a suction cup or adhesive pad that may be attached, for example, to a windscreen. However these goosenecks take up space and are unsightly. Moreover, this can make it more difficult for the weight of the device to be supported by the cradle at the end of the gooseneck.

Many of these mounting solutions are passive, and merely designed to hold an electronic device in a fixed position. If it is desired to form an electrical connection to the device when it is mounted, for instance to provide power to the device, then typically a separate power cable must be connected after the device has been located in the mount. The separate power cable may be connected to a cigarette lighter adapter in the vehicle. The position of such cradles inside the vehicle is often limited by a need to be able to easily attach a power cable and therefore the device can only be mounted in a certain number of ways. However it would be desirable to have greater flexibility in mounting a portable electronic device to a range of different surfaces within a vehicle, e.g. on the dashboard, on the windscreen, to the left or right of the steering wheel, or on a side window or other surface within view of the driver.

There is a growing number or portable electronic devices which are capable of providing in-car functions such as navigation, route planning, traffic updates, etc. These are often purchased for reasons other than navigation, e.g. digital music players, games consoles, smart phones, tablet computers etc. These devices typically have a colour display screen, and often a touch screen, and when in use they tend to suffer from a limited battery life. Such devices therefore necessitate the use of an electrical power connection in addition to suitable mounting. As is mentioned above, passive mounting solutions may rely on a separate charging cable connected to a cigarette lighter adapter. Other mounting solutions, typically permanent mounts in a vehicle, actively provide an electrical connection so that a user need to only locate a device in the cradle, and in so doing the device is docked on the mount's electrical power connector. There are, however, a number of drawbacks with currently available active mounts. For example, the cradles are often large and this means that they are confined to certain positions within a vehicle and are not always positioned optimally for a user to view the device. This may be exacerbated when trying to fit the same mount in different vehicles, which typically have a variable shape for the dashboard and a variable depth for the windscreen. There may also be issues with a mount interfering with a driver's view or operation of other controls in the vehicle and/or having an ugly appearance when the electronic device is removed. Edges or corners of the mount might present a hazard to the vehicle's occupants in the event of an accident.

Typically a mount that provides for active docking of an electronic device onto a power connector has a fixed orientation, e.g. so that the weight of the device is supported over the power connector and the device does not tend to tip forwards or backwards as this might compromise the electrical connection or damage the connector. However, this often means that it may be difficult to mount the device in a position where the device's screen is readily viewable by a user. Furthermore the position and/or angle of the mount can make it difficult for a user to quickly locate and/or remove the electronic device from the cradle, often requiring a number of actions to be performed in a specific order.

There remains a need for improved mounting solutions for portable electronic devices, and in particular portable navigation devices, that mitigate or reduce some of the above problems.

### SUMMARY OF THE INVENTION

According to a first aspect of the present invention there is provided a mount for a portable electronic device comprising: a support cradle arranged to engage against a surface of a device mounted thereto, the support cradle comprising a power connector having one or more electrical contacts to deliver electrical power to the device; and a bearing arrangement connecting the support cradle to the mount such that the support cradle is rotatable about at least two orthogonal axes passing through a fixed point defined by the mount.

According to the invention, it will be appreciated that when a device is mounted to the support cradle, it remains actively docked on the power connector while its position and/or angular orientation can be adjusted by rotating the support cradle relative to the mount. This means that the mount itself may be attached to any suitable surface in a vehicle, e.g. a dashboard or windscreen and the orientation of that surface no longer dictates the position of the device as the support cradle can be rotated relative to the mount to place the device in a desired position for use. Furthermore, such a mount may be used to dock a range of different devices which can each be mounted in the support cradle and moved to a position and/or angular orientation that takes into account the size of the device. A user can rotate the support cradle so as to angle the device to a desired viewing position and the device may be positioned at multiple different angles e.g. to suit different drivers, lighting conditions, etc.

In order to enhance the usability of the mount, the support cradle is preferably rotatable about three orthogonal axes passing through a fixed point defined by the mount. Thus a user may be able to adjust the support cradle so that a device mounted thereto is at any desired angular position. The support cradle may have any suitable shape allowing for rotation relative to the mount. In preferred embodiments the bearing arrangement comprises an outer surface of the support cradle that is at least partly spherical. This outer surface may be provided by the support cradle having the shape of a toroid, a spherical section (e.g. ball section) or a sphere (e.g. ball). Further preferably the bearing arrangement comprises an inner surface of the mount that is at least partly spherical. The inner surface of the mount may also take the form of a toroid, spherical section or sphere. The bearing arrangement may therefore take the form of a ball and socket joint, or a spherical bearing.

The applicant has recognised that when a support cradle is rotatably connected to a mount, there may be a risk of the cradle spinning or moving relative to the mount under its own weight. This may be exacerbated by the weight of an electronic device mounted to the support cradle, which may result in a torque tending to turn the support cradle away from a desired position. It is desirable that a user can rotate the support cradle so as to achieve a desired viewing position but without the support cradle rotating away from that position once a user has completed his adjustments. Thus in a preferred set of embodiments the bearing arrangement includes means for creating friction so that the support cradle cannot rotate freely relative to the mount. Preferably the outer surface and/or inner surface is provided with means for creating a frictional force that opposes rotation of the support cradle when a device is mounted thereto. Advantageously a user must apply a predetermined force to overcome the friction before the orientation of the support cradle can be adjusted.

Friction may be created by a variety of different means, e.g. hydraulic and/or mechanical. In example where an outer surface of the support cradle is provided with means for creating friction, such means may comprise, for example, a friction coating on the surface (e.g. an elastomeric coating) or surface features such as ribs or dimples etc. Alternatively, or in addition, an inner surface of the mount may be provided with friction-creating means such as, for example, a coating or insert (e.g. of an elastomeric material) or surface features that may create friction. The friction created in the bearing arrangement can counteract a torque acting on the support cradle due to the weight of a device mounted thereto, so that the cradle does not freely turn away from a user-adjusted position.

The support cradle may be connected to the mount such that it can be rotated by up to 360° about one, two or even three orthogonal axis. For example, it is mentioned above that the bearing arrangement may comprise a ball and socket joint. However, the range of movement of the support cradle must still allow an electrical connection to be made to the power connector. The electrical connection may be contactless, e.g. using induction or even radio frequency coupling, but such electrical connections are not typically suited to transmitting 12V DC as is typically required by a portable electronic device. It is preferable for an electrical cable to be coupled to the power connector. If the bearing arrangement takes the form of a solid ball and socket joint then such a cable may be led out of the support cradle rather than passing through the joint to the mount. However this may result in the cable getting in the way when a user mounts a device to the support cradle and is also likely to be unsightly. Rather it is preferred that the cable can pass from the support cradle through the bearing arrangement to the mount. The electrical cable can then be led out of the mount away from the support cradle and away from direct view.

Preferably the support cradle has a spherical outer surface provided by a hollow ball or ball section. If the bearing arrangement comprises a hollow ball and socket joint then the cable may pass through the joint, but this is likely to require a considerable length of cable to be accommodated inside the hollow ball so that there is plenty of slack if the ball is rotated through up to 360° in all three directions. Furthermore the slack length of cable is likely to become twisted inside the ball and this may compromise the integrity of the electrical connection.

In a preferred set of embodiments the support cradle comprises a hollow spherical section or toroid (i.e. a so-called spherical bearing) and the electrical cable passes therethrough to the mount. The toroid or hollow ball section ensures that the support cradle can be rotated by up to 360° around at least one of the orthogonal axes, but its rotation is limited to a particular angular range about the two other axes. It has been found that this still provides the support cradle with a relatively large degree of freedom in its orientation, as it may be swivelled fully (up to 360°) in one direction as well as being tiltable forward/backwards in another direction and side to side in a third direction. A benefit of such a spherical bearing is that the limited range of movement of the support cradle can be taken into account when an electrical cable is coupled to the power connector. Preferably the support cradle comprises a hollow ring or ball section that can accommodate the electrical cable. The cable may therefore pass from the power connector through the hollow support cradle to reach the mount and may then be led away from the mount so that it does not interfere with a user mounting or removing a device. This can also ensure that the mount is compact and visually appealing.

It will be appreciated that when an electrical cable is coupled to the power connector it necessarily moves relative to the mount whenever the support cradle is rotated to a different position. Depending on the way in which the support cradle is swivelled, this may result in the cable moving laterally and/or rotationally relative to the mount. These movements need to be accommodated so that the cable does not become twisted or tugged during adjustments of the support cradle. Preferably there is provided an unrestricted path for the cable from the power connector through the support cradle and through the mount. Where a spherical bearing is provided, the angular range of movement of the support cradle is known and this can be taken into account when providing the cable with enough slack. The outer toroidal or partly spherical surface of the support cradle may be provided with a lip at one or more of its edges so as to help ensure that the cradle does not over travel. This can also help to ensure that the support cradle does not pop out of the socket provided by the mount.

The applicant has devised various features to help relieve the electrical cable from strain as it moves relative to the mount. In one example, the support cradle has a diameter that is much greater than the diameter of the cable, which means that rotational movement of the support cradle translates into only small rotations of the cable. Accordingly the support cradle preferably has a diameter, defined between its outer toroidal or partly spherical outer surfaces, which is at least three, four, five or six times larger than the diameter of the cable. For example, the diameter of the support cradle may be between 20 and 30 mm.

As is discussed above, it can be important that the electrical cable coupled to the power connector is able to move together with the support cradle without becoming permanently twisted and without damaging the electrical connection to the power connector. The cable may be substantially flexible along its length so as to be able to move freely whenever the support cradle is rotated relative to the mount. However the applicant has found that it can actually be detrimental for the cable to be entirely flexible as this may encourage the formation of kinks or knots. Thus in a set of embodiments the electrical cable comprises a rigid section coupled to the power connector and a flexible section arranged to pass between the support cradle and the mount. The rigid section can ensure that the cable does not tug on the power connector, which may itself be coupled to the support cradle in a way that could be damaged by forces from the cable. Meanwhile the flexible section, spaced from the power connector by the rigid section, can twist and/or flex during rotation of the support cradle relative to the mount. The flexible section may be able to flex continuously e.g. due to a flexible sheath around the cable and/or the flexible section may be articulated e.g. comprising alternate rigid and flexible sub-sections.

The flexible section may be arranged to pass out from the mount e.g. through an aperture in the housing of the mount. However the applicant has found that a flexible cable is prone to rub against the edges of such an aperture as it flexes in different directions. Thus in a set of embodiments the electrical cable preferably comprises a further rigid section arranged to pass out from the mount e.g. through an aperture in the mount housing. The rigid section does not bend so its can slide forwards and backwards through the aperture, and rotate in the aperture, but without rubbing against the edges of the aperture. Preferably the aperture has a diameter that is larger than the diameter of the rigid section so as to ensure that it is free to slide and rotate.

The mount may be fixed to part of a vehicle or other surface in any suitable manner. The mount may be fixedly attached to a surface or even integrated for example with a dashboard of a vehicle such as a car, motorbike, bicycle of boat. The mount may be provided with attachment means enabling it to be attached to a suitable surface, for example a suction cup or adhesive pad. However a drawback of fixedly attaching a mount to a surface is that its orientation cannot then be easily adjusted. In a preferred set of embodiments the mount further comprises a base that allows for rotation of the mount in the plane of the base (i.e. around a z-axis orthogonal to the base). Accordingly the base may be fixedly attached to a surface in a vehicle or elsewhere, but the mount may be rotated around the axis to different positions in the xy plane. The mount may therefore be provided on a turntable. This can be particularly advantageous when the support cradle is connected to the mount by a spherical bearing which means that its range of angular movement is limited in some directions. When the mount is also rotatable on its base, this adds an additional degree of freedom which means that a user can both rotate the mount and then rotate the support cradle relative to the mount to ensure that an electronic device mounted to the cradle can be put into an optimal viewing position by the user.

The mount may be freely rotatable relative to the base, but especially in a vehicle there is a risk of the mount accidentally turning away from a desired position as a result of vibration or movement of the vehicle. Thus in a set of embodiments the mount is rotatably connected to a base with means being provided to lock the mount relative to the base. Rotation of the mount relative to the base may then only be allowed when the locking means is released. The locking means may comprise a latching engagement between the mount and the base. The base may include an upstanding peripheral wall arranged to receive the mount, the wall having an inwardly extending radial lip arranged to provide for latching engagement with the mount. The mount may be provided with one or more user-operated actuators that release the mount from latching engagement with the lip. For example, a spring-mounted actuator may be depressed to release the latching engagement from the lip. The base may be provided with indexing means that allow the mount to be rotated between discrete rotational positions.

The base may be provided on its underside with attachment means such as a suction cup or adhesive pad. In at least some embodiments the base is substantially circular e.g. having a discoid shape. An adhesive pad on the underside of the base may have an annular form so that it is better able to adhere to surfaces that are not entirely flat.

It will be appreciated that a mount according to the present invention, whether or not it includes a rotatably connected base as described above, can conveniently be mounted horizontally, vertically, or at an angle on various different surfaces, e.g. in a vehicle. The orientation of the base on an appropriate surface advantageously does not impinge on a user's ability to interact with or view an electronic device mounted to the support cradle, because the support cradle is itself rotatably connected to the mount and can be moved into a range of different orientations. However, when a support cradle is moved into different rotational positions, the weight of an electronic device mounted thereto will shift and may not be aligned over the power connector. A torque may therefore be applied which could potentially compromise electrical connection between the power connector and the electronic device. It is desirable for the weight of the device to be supported by the cradle without the device tending to pull away from its electrical connection with the power connector. In order to support the device, the support cradle may be arranged to engage against any suitable surface(s) of the device. These may be external and/or internal surfaces of the device. In a preferred example, if the support cradle can be inserted at least partially into a recess in the device then it may engage against an inner surface. This has been found to be particularly helpful in supporting the weight of the device, especially when it may be tilted forwards at an angle relative to the mount.

In a preferred set of embodiments the support cradle may comprise a protruding support for the electronic device that is insertable into a recess in a connector receiving assembly of the device in order to engage the power connector with a corresponding device connector to deliver electrical power to the device. By providing a protruding support that is insertable into a recess in a connector receiving assembly of the device, it is ensured that the support cradle can adequately bear the weight of the device as well as forming an electrical connection. The protruding support provides for mechanical engagement in addition to the electrical connection. The connector receiving assembly may be integrated with the device or attached thereto, e.g. fitted or retro-fitted to the device.

The protruding support may further preferably comprise a support surface extending in a plane substantially parallel to the electrical contact(s) of the power connector, and a pair of side walls each having an inner surface extending in a plane substantially transverse to the support surface. As the protruding support provides surfaces extending in at least two planes surrounding the power connector, the weight of the portable electronic device can be supported not only when it is mounted vertically on the mount but also when it is tilted through a range of angles. This means that the electronic device can be tilted forwards, backwards and/or side to side with its weight being supported by one or more surfaces of the protruding support. The power connector can maintain a firm electrical connection with the electronic device without being comprised by a torque that would tend to pull the device out of electrical connection if it were not supported by the surrounding surfaces.

Furthermore, it will be appreciated that when a protruding support is inserted into a recess in a corresponding connector receiving assembly of an electronic device, the weight of the device may be supported without a bulky support frame or the like extending around the outside of the device. A support cradle comprising a protruding support may therefore provide for a robust electrical connection and strong mechanical mounting yet one that has a compact profile. Furthermore, the protruding support can allow a user to locate the device, and to remove the device, with minimal effort e.g. using only one hand. In order to assist in supporting the device, the protruding support preferably protrudes from the cradle beyond the power connector.

In addition, or alternatively, it is preferable that at least one of the support surface and the inner surfaces of the side walls is/are spaced from the power connector and formed with part of a latch arrangement that receives a corresponding part of the connector receiving assembly to releasably retain the protruding support with the connector receiving assembly. Such a latch arrangement can ensure that an electronic device is securely mounted on the support cradle, regardless of its angle relative to the mount, by releasably retaining the protruding support within the connector receiving assembly. This means that the electronic device may even be angled so as to tip forwards from the support cradle, as the protruding support is retained within the connector receiving assembly by the latch arrangement.

Preferably the latch arrangement provides a retaining force that can be overcome by separating the connector receiving assembly from the protruding support. Thus the latch arrangement can be released simply through the action of separating the electronic device from the support cradle, which facilitates single-handed removal of the device. The retaining force may be provided by one or more of a frictional engagement, a magnetic interaction and/or a resilient connection. A resilient latch arrangement may be preferred, alone or in combination with another latching arrangement, as this may provide a retaining force that is strong enough for the device to be docked to the power connector while the support cradle is oriented across a range of angles, while also being easy enough to be overcome by a user simply pulling the device away from the protruding support. In one set of embodiments, at least one surface of the protruding support is formed with part of a latch arrangement comprising a resilient member or means for retaining a resilient member provided by the connector receiving assembly. Further details of such a latch arrangement are described in the applicant's co-pending application.

In addition, or alternatively, the shape of the protruding support may be designed to guide a device as it is mounted onto the cradle. Preferably the side walls of the protruding support are connected at a periphery of the support surface to form a substantially U-shaped or semi-circular support surrounding the power connector. Such a channel may help the protruding support to guide itself into the recess provided in the corresponding connector receiving assembly of an electronic device. In addition, or alternatively, each side wall of the protruding support may have an outer surface that is curved to assist in alignment of the protruding support as it is inserted into the recess. In addition, or alternatively, the protruding support may have an outer surface opposed to the supporting surface that is substantially circular to help guide insertion of the protruding support into the recess. This outer surface is preferably flat and arranged in a plane substantially parallel to the electrical contact(s) of the power connector, e.g. so that the protruding support is guided for insertion in a direction aligned with the power connector and its contacts.

The power connector may be of any suitable and desired form, but in a preferred set of embodiments the power connector comprises a USB connector, such as a micro- or mini-USB connector. The power connector may comprise either a male (plug) connector or a female (socket) connector as desired. In a preferred set of embodiments the power connector comprises a male connector plug that is insertable into a corresponding female socket of an electronic device. In embodiments where the support cradle comprises a protruding support as is described above, the power connector may be spaced from at least one, and preferably all, of the support surface and inner surfaces of the side walls of the protruding support. This makes space to receive a corresponding connector socket and also a corresponding part of a latch arrangement, where one is provided. The electrical contacts may form an electrical connection that transmits power and/or date between the power connector and a device mounted to the support cradle. Where the power connector is coupled to an electrical cable, the electrical contacts are preferably fixedly attached to corresponding conductors in the cable, e.g. by means of a soldered joint. The electrical cable may be coupled to the power connector in any suitable and desired manner. For example the power connector may be integrally moulded or over moulded with the electrical cable.

A mount as described hereinabove may be used to mount a portable electronic device, preferably a portable navigation device (PND), to a power connector in a vehicle such as a car, motorbike, bicycle, or boat, for example. The mount may further comprise one or more of: data storage means; a power adaptor; a voltage transformer; a loudspeaker, mobile telecommunication circuitry or devices; and a global navigation satellite system (GNSS) receiver, such as a global positioning system (GPS) receiver. The one or more electrical contacts of the power connector may be connected by a suitable circuitry to such electronic devices where provided in the mount.

The invention may find use in mounting a portable electronic device that is a touch screen device. The portable electronic device may comprise a mobile phone, smart phone, PDA, portable audio system (e.g. radio player, MP3 player), multi-media player, games console, tablet computer, portable personal computer or the like.

The present invention in accordance with any of its further aspects or embodiments may include any of the features described in reference to other aspects or embodiments of the invention to the extent it is not mutually inconsistent therewith.

Advantages of these embodiments are set out hereafter, and further details and features of each of these embodiments are defined in the accompanying dependent claims and elsewhere in the following detailed description.

### BRIEF DESCRIPTION OF THE DRAWINGS

Various preferred embodiments of the present invention will now be described, by way of example only, and with reference to the following figures, in which:

FIG. 1 is an exploded view of an exemplary mounting system for a portable electronic device including a mount in accordance with a first embodiment;

FIG. 2 is an exploded view of the mount;

FIG. 3 is a cross-sectional view of the mount;

FIGS. 4A to 4E show some detail of a connector receiving assembly in an electronic device arranged to engage with the mount;

FIGS. 5A to 5C show some detail of a latching arrangement between the connector receiving assembly and the mount;

FIG. 6A is a perspective view of the mount and FIGS. 6B and 6C show the mount in different mounting positions;

FIG. 7 is an exploded view showing the support cradle of the mount;

FIG. 8 is a partial cut-away view of the bearing arrangement in the mount;

FIGS. 9A to 9D illustrate rotation of the mount on its base; and

FIG. 10 is a perspective view of an alternative mount according to a second embodiment of the present invention.

### DETAILED DESCRIPTION OF THE INVENTION

The present invention, at least in preferred embodiments, relates to an active dock that provides an electrical connection for portable electronic devices that may be removably connected to a mount, in particular to portable navigation devices (PNDs) that may be mounted to a windscreen or dashboard in a vehicle. It is an aim of the present invention to provide a compact and attractive mounting solution wherein a user can quickly dock a portable electronic device with only one hand, irrespective of the device's size or shape.

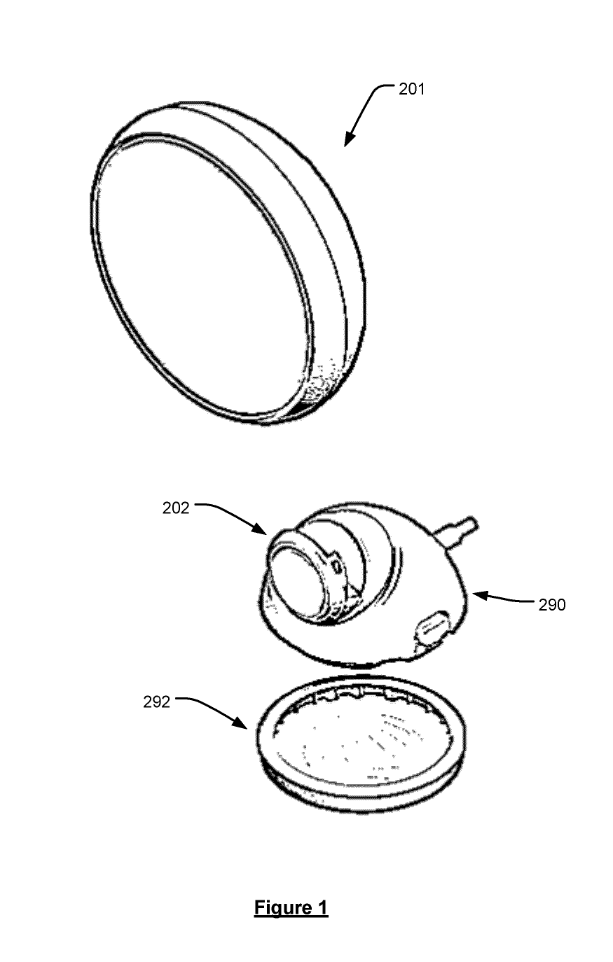

According to a first embodiment of the present invention, there is provided a connection system for connecting a portable navigation device 201 to a mount 290 as illustrated by FIGS. 1 to 9. The connection system comprises a support cradle 202 rotatably connected to a mount 290, 290′ and a corresponding connector receiving assembly 206 that is provided on or in the portable electronic device 201. It may be generally seen from FIG. 1 that the portable electronic device 201 is docked onto the support cradle 202 of a mount 290 that is provided with a mounting base 292, e.g. that can be adhesively attached to a dashboard or the like.

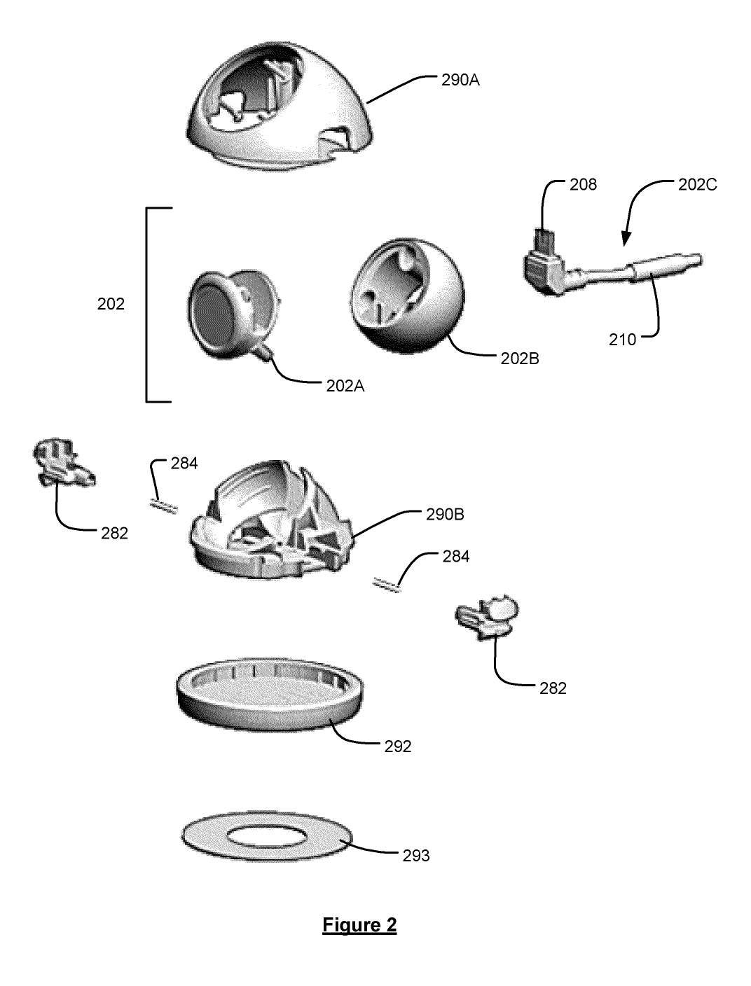

The various components of the mount 290 are shown in more detail in FIG. 2. The support cradle 202 comprises a protruding support part 202A, a rotatable ball section 202B and a cable assembly 202C in which an electrical power connector 208 is coupled to a cable 210. In the embodiment shown, the power connector 208 is a male micro-USB plug. The components of the support cradle 202 are fixedly connected together during assembly of the mount 290 so that they rotate together relative to the mount 290. Although in this embodiment the cable assembly 202C is a separate component that is attached to the protruding support part 202A, it will be understood that the protruding support part 202A may instead be fixedly attached to the power connector 208 of the cable assembly 202C e.g. by an integral plastics moulding.

The mount 290 comprises an upper mount cover 290A that receives the rotatable ball section 202B of the support cradle 202. Located between the ball section 202B and the mount cover 290A, the mount 290 includes a ball support 290B (seen in FIG. 2) that may create friction acting against rotation of the support cradle 202 in a manner that is described in relation to FIG. 8 below. The mount 290 is releasably connected to a base 292 that may be attached to a dashboard or other surface by an adhesive ring 293 provided on its underside. A pair of release buttons 282 are mounted by springs 284 on the ball support 290B so that a user can release the mount 290 from the base 292 as desired.

The mount 290 and support cradle 202 are seen together in FIG. 3. In this embodiment, the support cradle 202 comprises a rotatable ball section 202B that forms a partial ball and socket joint i.e. a spherical bearing within the upper mount cover 290A. Rotation of the ball section 202B is controlled by the ball support member 290B. The ball section 202B may be rotated within the spherical bearing so that the support cradle 202 can be oriented at different angles, both forwards and backwards and/or side to side, relative to the mount 290. This will be described in more detail below. It may also be seen from FIG. 3 that the power connector 208 is adjacent to a protruding support 204 that extends beyond the power connector 208 and can be inserted into a corresponding recess in a connector receiving assembly 206. The protruding support has side walls 212 that form a U-shaped support surrounding the power connector 208.

It is also seen from FIG. 3 that the power cable 210 extends in a direction away from the protruding support 204 and is led out through the hollow ball section 202B to exit the mount 290 through an aperture 230 at its rear to be connected to a suitable power source. The power cable 210 comprises a rigid section 210A coupled to the power connector 208, a flexible section 210B that extends through the hollow ball section 202B of the support cradle 202 to the mount 290, and an another rigid section 210C that passes out through the aperture 230. As the support cradle 202 is rotated relative to the mount 290 and the orientation of the power connector 208 changes, the cable 210 can slide forwards and backwards through the aperture 230 as well as turning. The central section 210B flexes so as to avoid any permanent cable twist that might compromise the electrical connection.

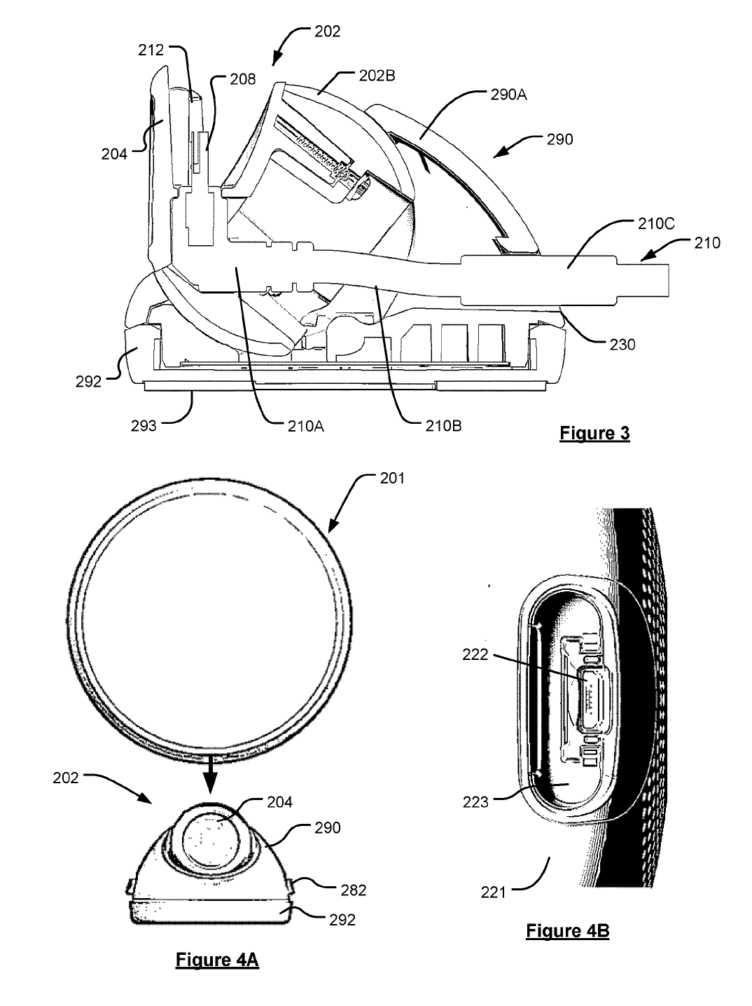

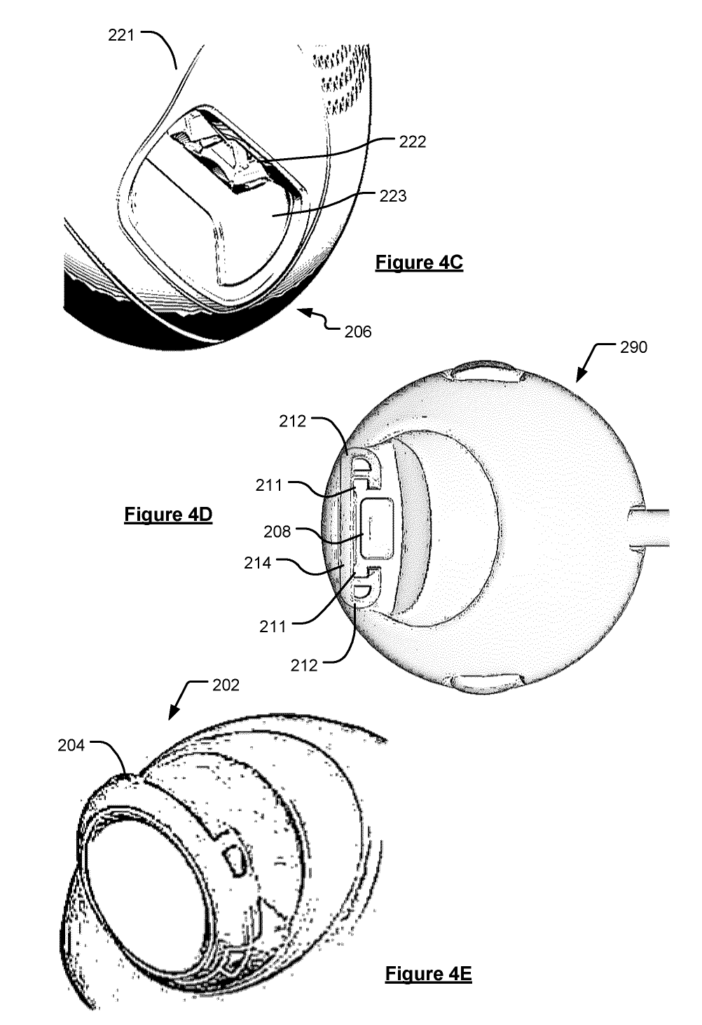

FIG. 4A provides a front view of a portable navigation device 201 being docked on to the support cradle 202 that is carried by the mount 290 seated on its base 292. FIGS. 4B and 4C show bottom and rear perspective views of the electronic device 201 and the electrical connector receiving assembly 206 formed within the housing 221 of the device 201. The connector receiving assembly 206 takes the form of a recess 223 that houses a device connector 222 and is arranged to receive the support cradle 202 in order to engage the device connector 222 with the corresponding power connector 208 to form an electrical connection for the device 201. FIGS. 4D and 4E provide top and side perspective views of the support cradle 202 in the mount 290. It can be seen that the protruding support 204 of the support cradle 202 is generally U-shaped in cross-section with a pair of side walls 212 extending either side of the power connector 208 and defining a pair of longitudinal grooves 211 that extend substantially parallel to the electrical contacts of the power connector 208. The side walls 212 are connected by a support surface 214 that has a generally flat surface on a side facing the power connector 208 and curved edges such that the protruding mount 204 has a circular form but is lozenge-shaped in cross-section.

When the support cradle 202 is engaged with the connector receiving assembly 206, the protruding mount 204 is inserted into the recess 223 while the power connector 208 is brought into engagement with the corresponding device connector 222. The side walls 212 and longitudinal grooves 211 in the protruding support 204 help to guide insertion of the support 204 so that the power connector 208 is aligned with the device connector 222. In this embodiment the device connector 222 is a female micro-USB socket. However, it will be appreciated that the plug and socket may of course be reversed. In order to accommodate the female socket 222 around the power connector plug 208, the support surface 214 and the side walls 212 are all spaced from the connector 208.

On the side of the support surface facing away from the power connector 208, the protruding support 204 is generally flat so as to co-operate with a corresponding flat inner surface of the recess 223 as the protruding support 204 is inserted therein. Similarly, the convex side walls 212 of the protruding support 204 co-operate with corresponding concave surfaces on the inside of the recess 223. These features all help to correctly align the support cradle 202 as it is inserted into the receiving assembly 206. Once the protruding support 204 is inserted into the recess 223, it provides for a mechanical engagement in addition to the electrical connection of the power connector 208 with the device connector 222. This means that the rotatable ball section 202B in the spherical bearing can be rotated so as to orient the support cradle 202 at different angles relative to the mount 290 and the weight of the electronic device 201 is supported by the support cradle 202 without comprising the electrical connection. In particular, the protruding support 204 enables the electronic device 201 to be tilted backwards through a range of angles and/or rotated from side to side.

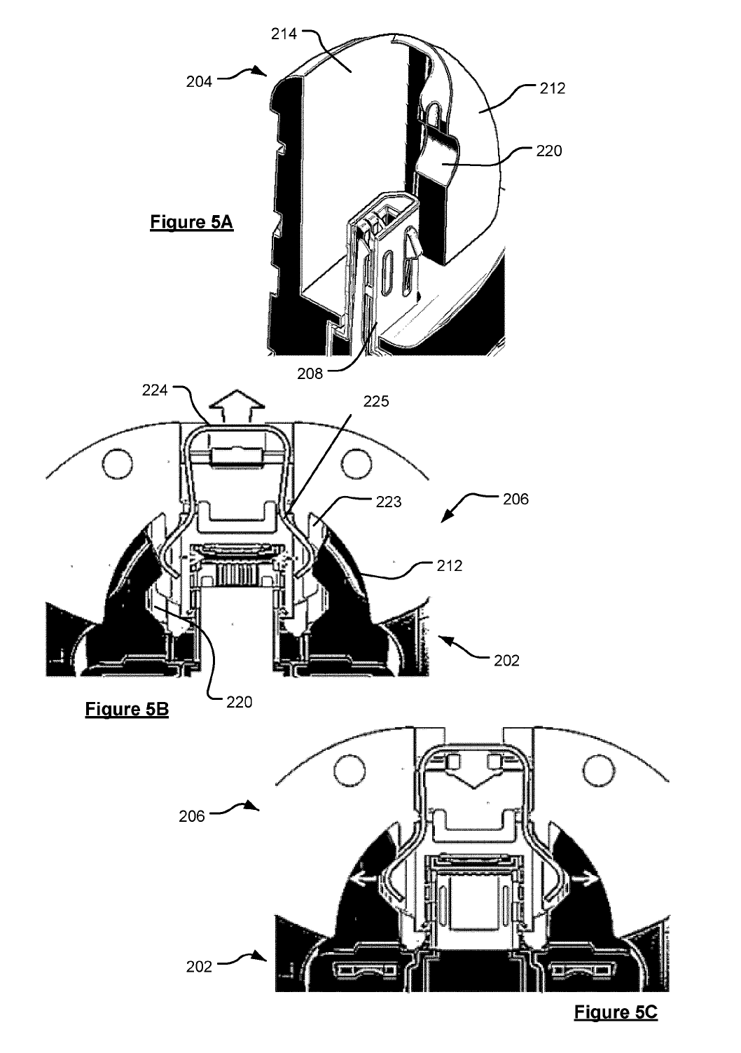

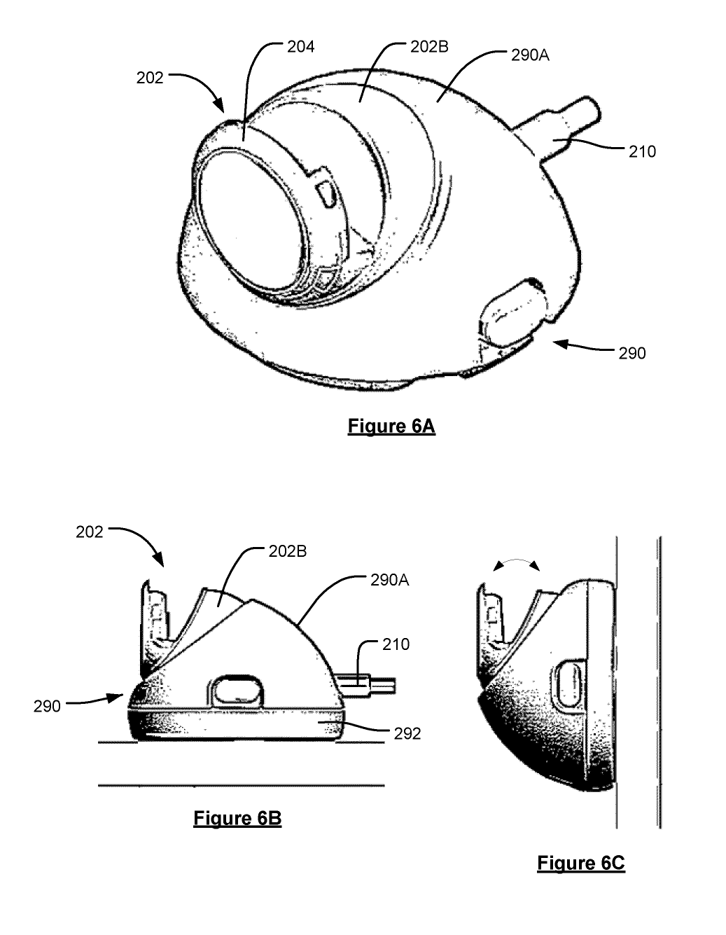

The connection system includes a latch arrangement that acts to releasably retain the protruding support 204 of the support cradle 202 within the connector receiving assembly 206 of an electronic device 201. The latch arrangement is illustrated in FIGS. 5A to 5C. Firstly, from the cut-away view shown in

FIG. 5A it can be seen that the protruding support 204 comprises a support surface 214 extending substantially parallel to the power connector 208 and a pair of side walls 212 that extend transverse to the support surface 214, with the support surface 214 and the inner surfaces of the side walls 212 being spaced from the power connector 208 so as to provide a generally U-shaped support surrounding the power connector 208. The side walls 212 are each formed with a notch 220 that forms part of the latch arrangement. The pair of notches 220 are positioned so as to receive a corresponding part of the connector receiving assembly 206 in the manner shown in FIGS. 5B and 5C.

In this embodiment the latch arrangement is a resilient latch arrangement comprising a resilient member 224 provided in the connector receiving assembly 206. The resilient member 224 takes the form of a generally V-shaped leaf spring that has a pair of spring legs 225 extending into the recess 223 so as to be insertable into the space surrounding the power connector 208 in the support cradle 202 (i.e. the space defined inside the U-shaped support 204). When the spring 224 is relaxed, its legs 225 extend through openings in the inner surface of the recess 223 so as to be contacted by the sidewalls 212 of the protruding support 204 when it is inserted into the recess 223. As the protruding support 204 is pushed into the recess 223, the legs of the spring 224 are compressed towards one another so that the U-shaped support 204 fills the recess 223. The resilient force of the spring 224 causes the legs 225 to relax outwardly and engage inside the notches 220 formed in the side walls 212 of the protruding support 204. The support cradle 202 is thereby retained within the connector receiving assembly 206 until a predetermined removal force is applied to overcome the spring bias and release the spring legs 225 from their engagement in the notches 220.

As will be appreciated, the spring 224 can be designed and constructed to provide a desired removal force. This may depend on factors including e.g. the size and/or weight of the portable electronic device 201 attached to the connector receiving assembly 206. Although in this embodiment a V-shaped leaf spring 224 is shown, of course one or more helical springs could be used instead. Indeed the latch arrangement is not limited to one comprising a resilient member and any other suitable latch arrangement may be provided instead, or in addition, so as to provide a desired retaining force. An advantage of a resilient latch arrangement as is described above is that a user can simply grip the portable device 201 in one hand and pull it away from the support cradle 202 protruding from the mount 290 with sufficient force to overcome the resilient bias of the spring 224 and thereby release the connector receiving assembly 206. However, it is envisaged that the latch arrangement may use other, or additional, means to provide a retaining force that can be overcome by separating the connector receiving assembly 206 from the protruding support 204. For example, a magnetic retaining force may be employed.

FIGS. 6A to 6C illustrate how the support cradle 202 may be angled into different positions relative to the mount 290. Depending on the orientation of the mount 290, a user may re-orient the support cradle 202 as desired by rotating the ball section 202B within the spherical bearing that connects it to the mount 290. For example, in FIG. 6B the mount 290 is shown mounted horizontally onto a dashboard with the support cradle 202 oriented substantially transverse to the base 292 so that an electronic device docked on the support cradle 202 is oriented generally vertically. In FIG. 6C it is seen that the mount 290 may instead be mounted generally vertically and then the ball section 202B may be tilted back into the mount cover 290A so that the support cradle 202 is oriented substantially parallel to the base 292 and an electronic device 201 docked on the support cradle 202 therefore remains vertical for ease of viewing. Of course, the support cradle 202 may be oriented at various angles therebetween. It will be appreciated that re-orientation of an electronic device 201 is facilitated by the protruding support member 204 of the support cradle 202, which acts to support the weight of the electronic device 201 and provides for stable mounting regardless of its orientation.

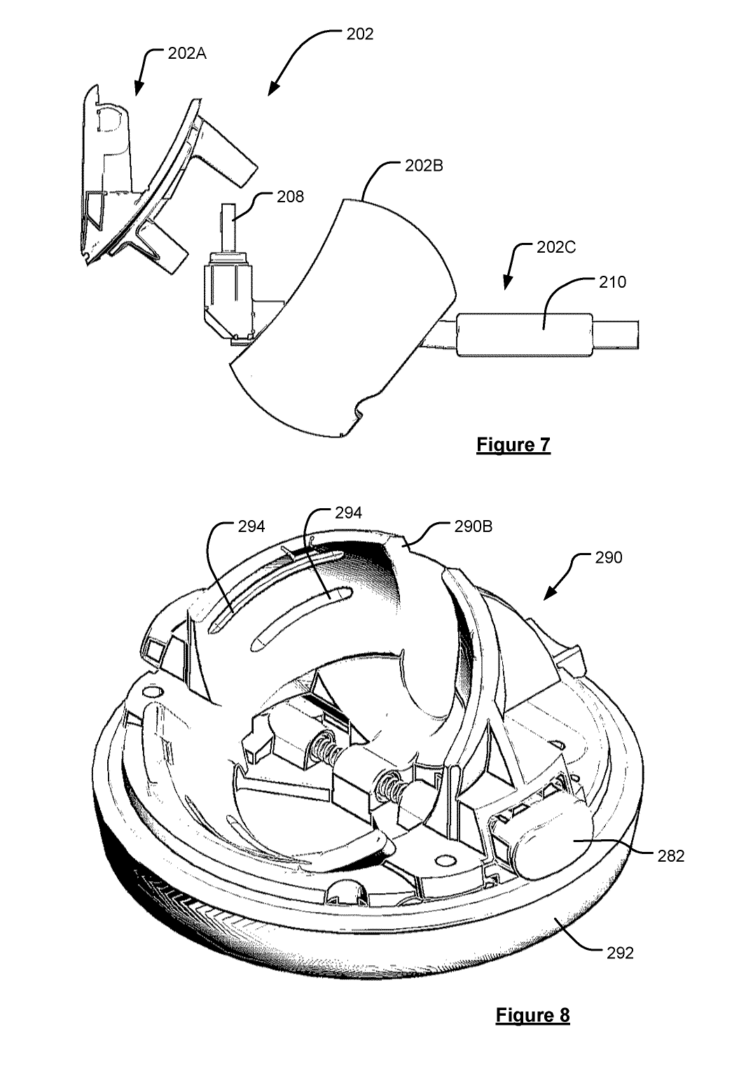

From the exploded view of FIG. 7 it may be seen that the support cradle 202 is assembled from three different components, namely the protruding support part 202A, the hollow ball section 202B and the cable assembly 202C. A benefit of designing the support cradle 202 in this way is that a standard cable 210 carrying a USB connector plug 208 may be used, rather than needing to design a bespoke USB connector for the mount 290. The ball section 202B takes the form of a toroid, i.e. a hollow ring with a spherical outer surface, which means that the cable assembly 202C is easily passed therethrough. The protruding support part 202A then locates over the USB connector plug 208 when the components are assembled together. The resulting support cradle 202 has a generally rounded appearance from the front so that, in combination with the mount cover 290A, the mount 290 has an overall spherical or ball-like appearance without any sharp corners or edges.

Turning to FIG. 8, there is seen part of the ball support 290B that is fixed inside the outer cover 290A of the mount 290. The ball support 290B has a partly spherical inner surface that is shaped to match the outer surface of the ball section 202B and thereby form a spherical bearing connecting the support cradle 202 to the mount 290. The support cradle 202 cannot rotate entirely freely within the mount 290, as the ball support 290B is provided with one or more features 294 on its inner surface that create friction tending to counteract rotation of the support cradle 202. In the embodiment illustrated, the features 294 take the form of ribs along the inner surface of the ball support 290B, but of course any suitable friction-creating feature or surface finish may be employed. For example, the ball support 290B may take the form of a part spherical elastomeric insert that is seated inside the outer mount cover 290A. The friction created by the ball support 290B may be in combination with, or replaced by, a friction-creating surface finish or features on the part spherical outer surface of the ball section 202B, for example an elastomeric coating on the outer surface. It will be appreciated that the way in which friction is created may be chosen so as to obtain a desired frictional force that will counteract movement of the cradle support 202 under an applied torque typically expected from mounting a portable electronic device, such as a portable navigation device.

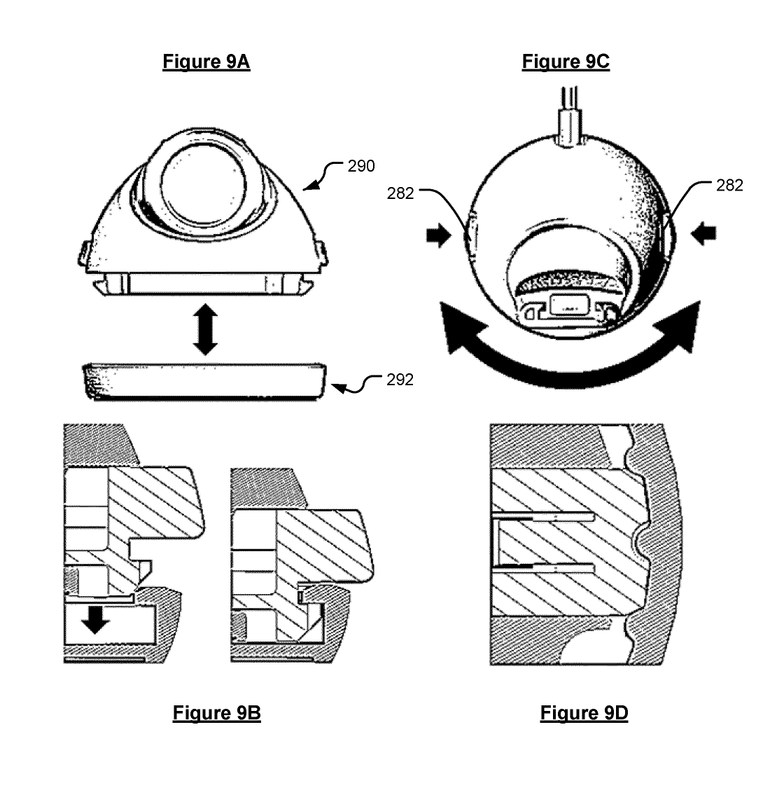

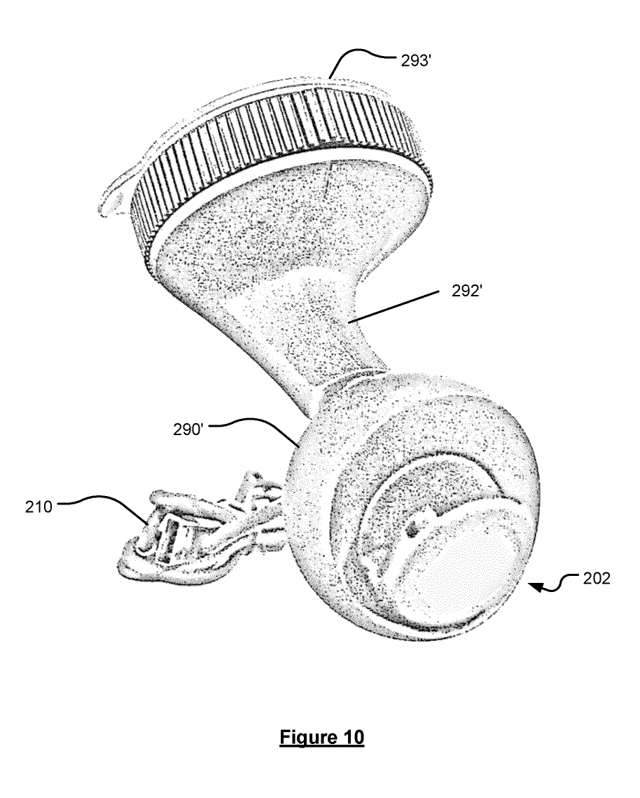

From FIGS. 9A and 9B it will be understood that the mount 290 is releasably attached to the base 292 with a latch arrangement acting to lock the mount 290 under a lip formed around the outer perimeter of the base 292. From FIGS. 9C and 9D it can be seen that depressing the buttons 282 enables the mount to be rotated in the plane of the base 292 to a different rotational position. The buttons 282 interact with indexing features inside the base 292 so that the mount 290 is locked in a rotational position once the buttons 282 are released. The buttons 282 may be mounted against springs 284 (seen in FIG. 2) so that they automatically move out once a user releases them to provide an indexing engagement. In embodiments, and to limit a rocking motion of the mount 290 when positioned in the base 292, a one or more, and preferably a plurality of, projections are provided on the base of the mount.

FIG. 10 shows an alternative type of mount 290′ according to a second embodiment that is intended to be mounted to a windscreen rather than to a dashboard. This alternative mount 290′ carries a support cradle 202 which is the same as described above, rotatably connected to the mount 290′ by a ball and socket joint or spherical bearing. The mount 290′ has a base 292′ that includes a gooseneck spacing the mount 290′ from a suction cup 293′.

A mount according to embodiments of the present invention is particularly suited to mounting portable navigation devices with touch screens which may be configured to execute navigation software so as to provide one or more navigation-related functions such as e.g. route planning, destination information, traffic information, real-time traffic updates, estimated time of arrival, alternative route suggestions, favourite destinations, etc.

It will be appreciated, however, that the mounts described herein can be used with any type of portable electronic device, such as a portable personal computer, mobile telephone, smart phone, PDA, portable audio system (e.g. radio player, MP3 player), multi-media player, games console or tablet computer.

As will be appreciated by those skilled in the art, various changes and modifications can be made to the above described embodiments whilst still falling within the scope of the present invention as set forth in the accompanying claims.

1. A mount for a portable electronic device, comprising:
a support cradle arranged to engage against a surface of a device mounted thereto, the support cradle comprising a power connector having one or more electrical contacts to deliver electrical power to the device;
a bearing arrangement connecting the support cradle to the mount such that the support cradle is rotatable about at least two orthogonal axes passing through a fixed point defined by the mount; and
an electrical cable coupled to the power connector, the electrical cable passing from the support cradle through the bearing arrangement to the mount.

2. The mount of claim 1, wherein the bearing arrangement comprises an outer surface of the support cradle that is at least partly spherical.

3. The mount of claim 1, wherein the bearing arrangement comprises an inner surface of the mount that is at least partly spherical.

4. The mount of claim 2, wherein the outer surface and/or inner surface is provided with means for creating a frictional force that opposes rotation of the support cradle when a device is mounted thereto.

5. The mount of claim 1, wherein the support cradle comprises a hollow spherical section or toroid and the electrical cable passes therethrough to the mount.

6. The mount of claim 1, wherein the electrical cable comprises a rigid section coupled to the power connector and a flexible section arranged to pass between the support cradle and the mount.

7. The mount of claim 1, wherein the electrical cable comprises a rigid section arranged to pass out from the mount.

8. The mount of claim 1, comprising a base that allows for rotation of the mount around an axis orthogonal to the plane of the base.

9. The mount of claim 8, wherein the mount is locked relative to the base by a latching engagement between the mount and the base.

10. The mount of claim 8, wherein the base is provided with indexing means that allow the mount to be rotated between discrete rotational positions.

11. (canceled)

12. The mount of claim 1, wherein the support cradle comprises a protruding support for an electronic device that is insertable into a recess in a connector receiving assembly of the device in order to engage the power connector with a corresponding device connector to deliver electrical power to the device.

13. The mount of claim 12, wherein the protruding support comprises a support surface extending in a plane substantially parallel to the one or more electrical contacts of the power connector, and a pair of side walls each having an inner surface extending in a plane substantially transverse to the support surface.

14. The mount of claim 13, wherein the side walls of the protruding support are connected at a periphery of the support surface to form a substantially U-shaped or semi-circular support surrounding the power connector.

15. The mount of claim 12, wherein at least one of the support surface and the inner surfaces of the side walls is spaced from the power connector and formed with part of a latch arrangement that receives a corresponding part of the connector receiving assembly to releasably retain the protruding support with the connector receiving assembly.

16. The mount of claim 15, wherein the latch arrangement provides a retaining force that can be overcome by separating the connector receiving assembly from the protruding support.

17. The mount of claim 15, wherein at least one surface of the protruding support is formed with part of a latch arrangement comprising a resilient member.

18. The mount of claim 1, wherein the power connector comprises a male connector plug.

19. An electrical connection system comprising a portable electronic device, docked to a mount according to any preceding claim 1.

20. The mount of claim 15, wherein at least one surface of the protruding support forms part of a latch arrangement and comprises a retaining profile for a resilient member provided by the connector receiving assembly.
